(19) United States
(12) Patent Application Publication
(10) Pub. No.: US 2006/0113879 A1
(43) Pub. Date: Jun. 1, 2006

(54) Piezoelectric micro acoustic sensor based on ferroelectric materials

(76) Inventors: Tianling Ren, Beijing (CN); Yi Yang, Beijing (CN); Yiping Zhu, Beijing (CN); Litian Liu, Beijing (CN)

Correspondence Address: KNOBBE MARTENS OLSON & BEAR LLP, 2040 MAIN STREET, FOURTEENTH FLOOR, IRVINE, CA, 92614, US

(21) Appl. No.: 11/251,102

(22) Filed: Oct. 14, 2005

(30) Foreign Application Priority Data
Oct. 15, 2004 (CN) 200410009668.9

(51) Int. Cl. H01L 41/047

(52) U.S. Cl. 310/366

(57) ABSTRACT

The present invention relates to a piezoelectric micro acoustic sensor based on ferroelectric materials. In one embodiment, more than one electrode pairs are provided within at least one of the central portion and the peripheral portion of a ferroelectric film of the sensor, a polarizing voltage is applied to each electrode pair so that regions of the ferroelectric film between each electrode pair is polarized along the thickness direction, and in a same stress state portion of the film regions of the ferroelectric film between neighboring electrode pairs are polarized in opposite directions, hence the neighboring electrode pairs within the same stress state portion have opposite voltages when the ferroelectric film vibrates. In one embodiment, all of the electrode pairs are connected in series, so that the output voltage of thus connected electrode pairs equals to the sum of voltages of each single pair. Therefore the voltage sensitivity of the piezoelectric micro acoustic sensor is improved significantly.

### FIELD OF INVENTION

The present invention relates to a micro acoustic sensor, and more particularly, to a piezoelectric ferroelectric micro acoustic sensor based on ferroelectric materials.

### DESCRIPTION OF THE RELATED TECHNOLOGY

Piezoelectric micro acoustic sensors are widely used in audio frequency and ultrasonic frequency bands with portable devices, such as microphones of cellular phones, hearing aids, monitoring equipments, telemeters, biomedicine imaging devices, lossless detectors. Manufactured with micromachining and microfabrication process, a micro acoustic sensor has the advantages of small size, low cost of manufacturing and could be integrated into on-chip circuits. In addition, a micro acoustic sensor can be produced with simple processes, and can operate with high reliability under a variety of circumstances. Low sensitivity, however, is a drawback of piezoelectric micro acoustic sensors.

FIG. 1 is a cross-sectional view of a conventional piezoelectric micro acoustic sensor whose piezoelectric film 104 is made of ferroelectric materials. A supporting layer 102, a lower electrode 103, ferroelectric film 104, an upper electrode 105 and an isolation layer 106 are sequentially stacked on a substrate 101 so as to form a diaphragm with a multilayered structure. The upper electrode 105 and the lower electrode 103 constitute an electrode pair. By via holes 108, metal bonding layers 107 are electrically connected to the upper electrode 105 and the lower electrode 103 of the electrode pair. Before the piezoelectric micro acoustic sensor based on ferroelectric materials begins to convert acoustic signals into electric signals, in other words, before it enters a working state, a polarizing voltage needs to be applied to the electrode pair through metal bonding layers 107, the polarizing voltage V_{polarizing} being a voltage that is necessary to enable the ferroelectric material between the electrode pair to be polarized in the electric field generated by the electrode pair. The micro acoustic sensor is then in a working state, and the metal layers 107 function as output terminals through which a voltage induced between the upper electrode 105 and the lower electrode 103 due to vibration of the ferroelectric film 104 is output. The substrate 101 may be made of any of the semi-conductive materials selected from the group comprising monocrystal silicon, GaAs, GaN and InP, and the ferroelectric film 104 may be made of any of the ferroelectric materials selected from the group comprising PZT, PT and PVDF, whose direction of polarization can be easily controlled.

It's to be noted that like reference numerals refer to like, similar or corresponding elements or functions throughout the following figures, for example, the lower electrode in FIG. 3 is indicated as 303 and the lower electrode in FIG. 4 as 403. For ease of simplicity, descriptions to the same or similar elements are therefore omitted hereafter.

An opening 100 with linear dimension as L is formed on the substrate 101 by wet etching or dry etching, so as to expose the supporting layer 102. Due to presence of the opening 100, the multilayer diaphragm of the piezoelectric micro acoustic sensor can vibrate under the pressure produced by sounds, so as to cause a stress distribution within the ferroelectric film.

When a diaphragm is vibrating, its central portion and peripheral portion have opposite stress states. FIG. 2 shows schematically the two stress state portions of a square film having a side length of L, i.e., a central portion 210 and a peripheral portion 211, the two portions bordering each other at a border line 209. When one of the stress state portions is in tension, the other one is always in compression. As shown in FIG. 2, the central portion has a square shape with a side length of about 0.7L. In the case where the film is round with a radius of R, it has a round central portion with a radius of 0.7R.

A brief introduction will be given below to the principle of a piezoelectric micro acoustic sensor based on ferroelectric materials.

Firstly, the ferroelectric film 104 is polarized along its thickness direction by applying a polarizing voltage V_{polarizing} between the upper and lower electrodes. When the ferroelectric film vibrates as driven by sound waves, a potential difference v (also referred as a voltage v hereafter) between the upper and lower electrodes 105 and 103 is generated, and an acoustic signal is therefore converted into an electric signal. In the case where the stress state of the ferroelectric film between an electrode pair 105 and 103 remains unchanged, when the direction of polarization of the ferroelectric film is reversed, the voltage v is reversed accordingly. In the case where the direction of polarization of the ferroelectric film remains unchanged, when the stress state of the ferroelectric film is reversed, for example, from tension to compression, the voltage v is also reversed.

In the case where the ferroelectric film of a piezoelectric micro acoustic sensor based on ferroelectric materials is polarized in its thickness direction so as to have the central portion 210 and the peripheral portion 211 polarized in the same direction, and the upper and lower electrodes extend across the border line 209 and cover both of the portions, the two portions will induce opposite voltages on the same electrode pair 105 and 103 respectively to counteract each other when the ferroelectric film vibrates, and the voltage sensitivity of the piezoelectric micro acoustic sensor based on ferroelectric materials is thus deteriorated.

To increase the voltage sensitivity, the electrode pair shall be provided either in the central portion as shown in FIG. 3 or in the peripheral portion of a ferroelectric film of a piezoelectric ferroelectric micro acoustic sensor based on ferroelectric materials, so as to avoid opposite voltages being induced on the same electrode pair. Alternatively, it's acceptable to provide two electrode pairs as shown in FIG. 4, one electrode pair 412 and 403 being disposed in the central portion, the other pair 413 and 403 in the peripheral portion, a polarizing voltage being applied to the two electrode pairs respectively to enable the regions of ferroelectric film between the two electrode pairs to be polarized in the same direction along the thickness direction (FIG. 4b shows an example where the film is polarized downwardly in both portions). The two electrode pairs are connected in series by connecting electrically the two lower electrodes, and the output voltage of the two electrode pairs thus connected therefore is the sum of the voltage of each of them, hence the voltage sensitivity is increased further.

### SUMMARY OF CERTAIN INVENTIVE ASPECTS

One aspect of he present invention makes an improvement on the prior art by disposing a plurality of electrode pairs in the same stress state portion of the ferroelectric film, and provides a method for controlling the direction of polarization of the ferroelectric film between each electrode pair and the connection of the electrode pairs. The voltage sensitivity according to one embodiment of the present invention is improved significantly.

Another aspect of the invention is provides a piezoelectric micro acoustic sensor based on ferroelectric materials with improved voltage sensitivity. In one embodiment, the sensor includes a ferroelectric film, and a plurality of electrode pairs, the two electrodes in each pair being disposed on either side of the ferroelectric film to mutually face each other, wherein each of said plurality of electrode pairs is either disposed in the central portion or the peripheral portion of the ferroelectric film, and more than one electrode pairs are provided within at least one of the central portion and the peripheral portion, and wherein a polarizing voltage is applied to each electrode pair so that regions of the ferroelectric film between each electrode pair is polarized along the thickness direction, in a same stress state portion of the film, and regions of the ferroelectric film between neighboring electrode pairs are polarized in opposite directions, so that the neighboring electrode pairs within a same stress state portion have opposite voltages when the ferroelectric film vibrates. In one embodiment, in each stress state portion of the ferroelectric film, the electrode pairs are connected in series by electrically connecting every electrode pair with its neighboring pair, wherein the regions of ferroelectric film between the two neighboring pairs are polarized in opposite directions, and the electrode pairs connected in series in both the stress state portions are connected in series again, so that all the electrode pairs are connected in series, and the output voltage of thus connected electrode pairs equals to the sum of voltages of each single pair. Therefore the voltage sensitivity of the piezoelectric micro acoustic sensor based on ferroelectric materials is improved significantly.

### BRIEF DESCRIPTION OF THE DRAWINGS

Embodiments of the present invention will be described with reference to the drawings.

FIG. 1 is a cross-sectional view of a conventional piezoelectric ferroelectric micro acoustic sensor based on ferroelectric materials.

FIG. 2 shows schematically the two stress state portions, i.e., a central portion 210 and a peripheral portion 211 of a square film having a side length of L.

FIG. 3a is a perspective view of an arrangement of an electrode pair of a conventional piezoelectric ferroelectric micro acoustic sensor based on ferroelectric materials.

FIG. 3b shows a method of applying a polarizing voltage to the electrode pair shown in FIG. 3a.

FIG. 4a shows schematically an example of the arrangement of two electrode pairs in a conventional piezoelectric ferroelectric micro acoustic sensor based on ferroelectric materials.

FIG. 4b shows a method of applying a polarizing voltage to the electrode pairs shown in FIG. 4a to polarize the ferroelectric film therebetween.

FIG. 5a is a perspective view showing an arrangement of the electrode pairs of a piezoelectric micro acoustic sensor based on ferroelectric materials according to embodiment 1 of the present invention.

FIG. 5b shows a method of applying a polarizing voltage to the electrode pairs shown in FIG. 5a to polarize the ferroelectric film therebetween.

FIG. 5c shows another method of applying a polarizing voltage to the electrode pairs shown in FIG. 5a.

FIG. 6a is a perspective view showing an arrangement of the electrode pairs of a piezoelectric micro acoustic sensor based on ferroelectric materials according to embodiment 2 of the present invention.

FIG. 6b shows the layout of the upper electrodes and their connections shown in FIG. 6a.

FIG. 6c shows the layout of the lower electrodes and their connections shown in FIG. 6a.

FIG. 6d shows an equivalent circuit of the piezoelectric micro acoustic sensor based on ferroelectric materials shown in FIG. 6a.

FIG. 6eshows a method of applying a polarizing voltage to the electrode pairs shown in FIG. 6a to polarize the ferroelectric film therebetween.

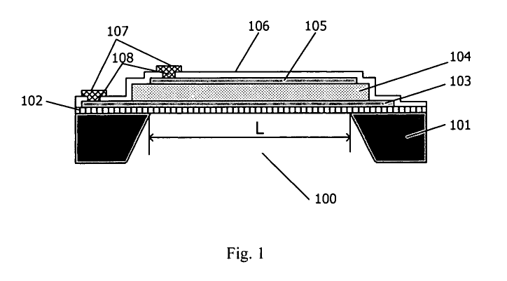

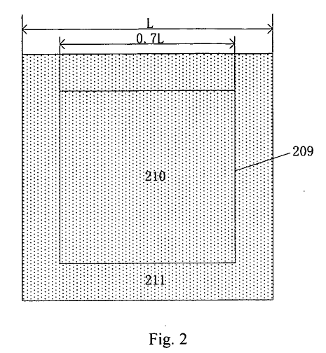

### DETAILED DESCRIPTION OF CERTAIN INVENTIVE EMBODIMENTS

The following describes embodiments of the present invention with reference to the accompanying drawings.

### Embodiment 1

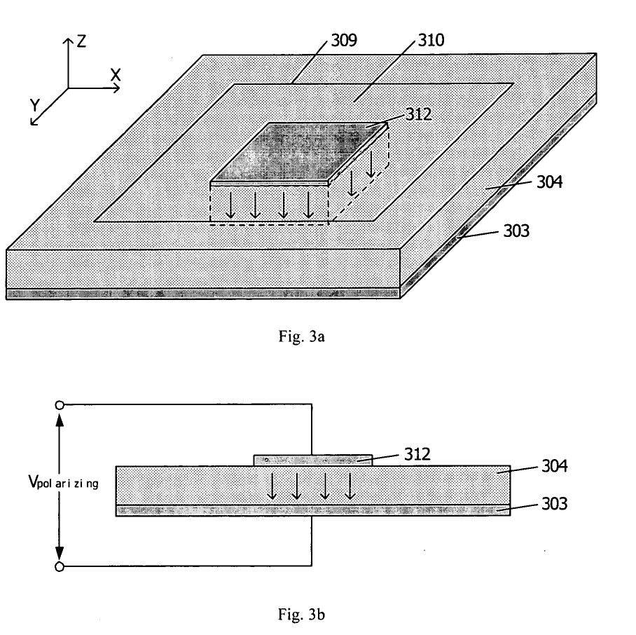

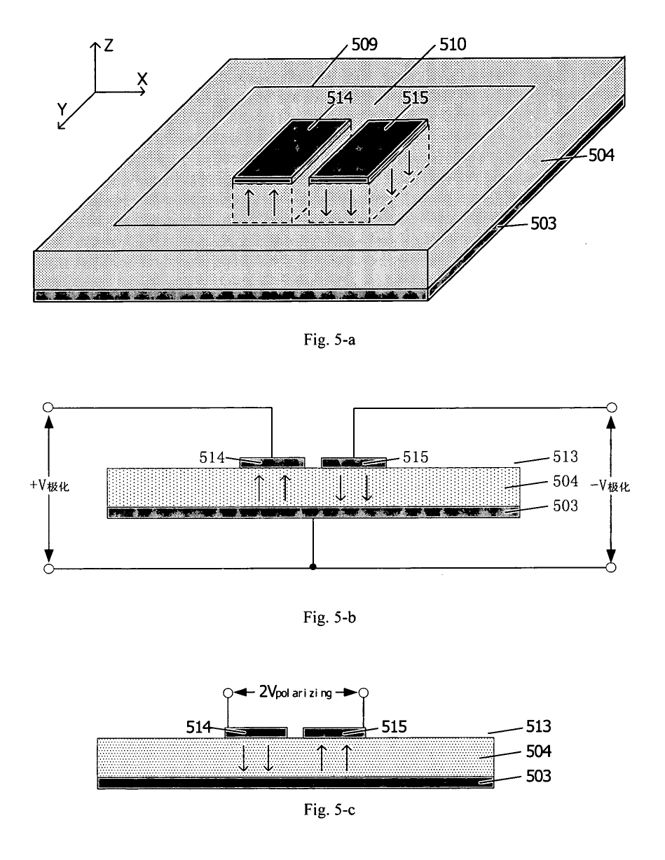

A piezoelectric micro acoustic sensor based on ferroelectric materials shown in FIG. 5a comprises two electrode pairs, i.e., electrode pair 514 and 503, and electrode pair 515 and 503, both of which are disposed within the central portion of the ferroelectric film. The two lower electrodes are formed integrally as shown in FIG. 5a, and alternatively, they may be produced separately and electrically connected to each other. The two electrode pairs in FIG. 5a can be regarded as being formed by equally splitting the electrode pair 312 and 303 in FIG. 3a into two. Therefore, each of the two electrode pairs shown in FIG. 5a has a capacitance which is approximately half of that of the electrode pair 312 and 303, and the amount of the electric charge induced on each of the two electrode pairs is also about half of that induced on the electrode pair 312 and 303. A voltage induced on each of the two electrode pairs thus remains substantially equal to that of the electrode pair 312 and 303.

The regions of ferroelectric film between the two electrode pairs are polarized in opposite directions, as shown in FIG. 5b.

Alternatively, through two terminals, which are connected to electrodes 514 and 515 (FIG. 5c), a voltage, two times as large as the polarizing voltage, is applied to the two electrode pairs, and the ferroelectric film is polarized similarly as that shown in FIG. 5b. Therefore, the ferroelectric film is polarized in a simplified and more convenient manner.

When the ferroelectric film vibrates, the two electrode pairs generate opposite voltages, and they are connected in series. The total voltage output from the two terminals shown in FIG. 5c is therefore two times as large as that of each of the electrode pair, and the voltage sensitivity of the sensor is improved.

In addition, the ferroelectric film can be polarized with different methods, (1) by applying opposite polarizing voltages V_{polarizing} to the two electrode pairs respectively, as shown in FIG. 5b, so that the regions of ferroelectric film located between the two electrode pairs are polarized in opposite directions; and (2) by applying a voltage that is at least two times as large as V_{polarizing} to the terminals connected to electrodes 514 and 515, as shown in FIG. 5c, so that electrodes 514 and 515 have opposite electric charges in the electric fields caused by the charges on the two electrodes, and the two regions of the ferroelectric film located between the two electrode pairs are polarized in opposite directions, which is similar as that shown in FIG. 5b. In this way, the circuit for polarizing the ferroelectric film is simplified, and the film could be polarized more conveniently.

### Embodiment 2

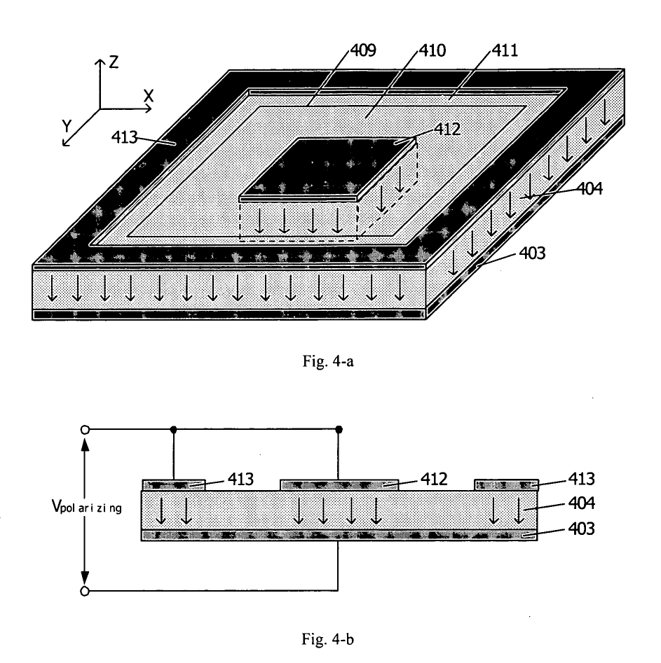

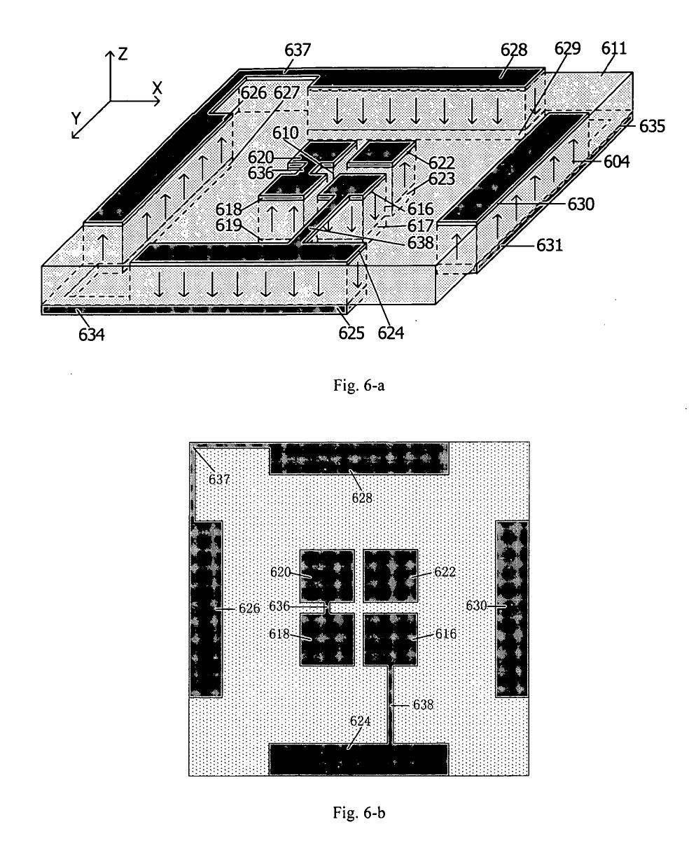

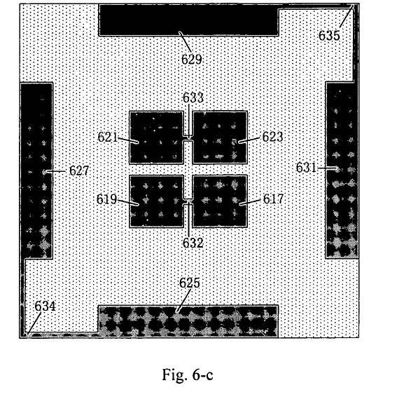

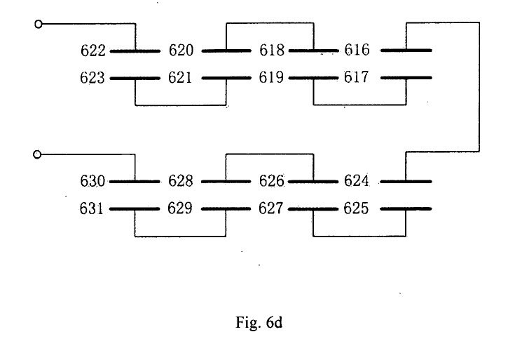

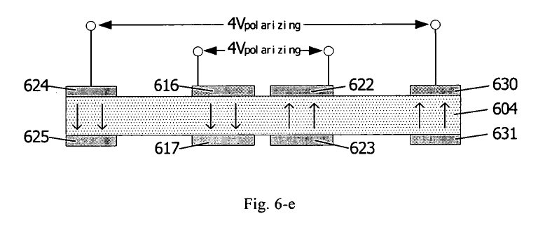

FIGS. 6a, b, c show another piezoelectric micro acoustic sensor based on ferroelectric materials having a square shape according to embodiment 2 of the present invention, which comprises four central electrode pairs located within the central portion of the ferroelectric film, i.e., electrode pairs 616 and 617, 618 and 619, 620 and 621, 622 and 623, and four peripheral electrode pairs located within the peripheral portion thereof, i.e., electrode pairs 624 and 625, 626 and 627, 628 and 629, 630 and 631. The four central electrode pairs can be regarded as being formed by equally splitting the central electrode pair 412 and 413 shown in FIG. 4a into four parts, and for the same reason as described in embodiment 1, each of the four separated central electrode pairs has substantially a same voltage as when they were formed integrally. Similarly, the four peripheral electrode pairs can be regarded as being formed by splitting the electrode pair 413 and 403 into four parts, and each of the four peripheral electrode pairs keeps its voltage substantially unchanged after being separated from an integral one.

Each of the central electrode pairs and each of the peripheral electrode pairs are electrically connected as follows. As shown in FIG. 6b, an upper connection 636 connects the central electrode pair 618 and 619 to its neighboring central electrode pair 620 and 621; an upper connection 637 connects the peripheral electrode pair 626 and 627 to its neighboring peripheral electrode pair 628 and 629; and an upper connection 638 connects the central electrode pair 616 and 617 to its neighboring peripheral electrode pair 624 and 625. As shown in FIG. 6c, a lower connection 632 connects the central electrode pair 616 and 617 to its neighboring central electrode pair 618 and 619; a lower connection 633 connects the central electrode pair 620 and 621 to its neighboring central electrode pair 622 and 623; a lower connection 634 connects the peripheral electrode pair 624 and 625 to its neighboring peripheral electrode pair 626 and 627; and a lower connection 635 connects the peripheral electrode pair 628 and 629 to its neighboring peripheral electrode pair 630 and 631.

By applying a polarizing voltage to the above-described electrode pairs so that the ferroelectric materials of the ferroelectric film 604 between each electrode pairs are polarized in the thickness direction of the film, it is arranged that, in both of the central portion and the peripheral portion, regions of ferroelectric film between neighboring electrode pairs are polarized in opposite directions, so that the electrically connected neighboring electrode pairs in a same stress state portion have opposite voltages. Regions of ferroelectric film between central electrode pair 616 and 617 and peripheral electrode pair 624 and 625 which are connected by the upper connection 638 are polarized in the same direction, therefore the two electrode pairs also have opposite voltages, as shown in FIG. 6a.

FIG. 6d shows an equivalent circuit of the piezoelectric micro acoustic sensor based on ferroelectric materials shown in FIG. 6a. It's apparent from FIG. 6d that all the electrode pairs are connected in series, and the voltage output from electrodes 622 and 630 is the sum of voltages generated by each electrode pair. The voltage sensitivity of the piezoelectric micro acoustic sensor based on ferroelectric materials according to this embodiment is four times as large as that of a conventional one as shown in FIG. 4.

Similar to embodiment 1, when polarizing the ferroelectric film, it's acceptable to apply a polarizing voltage V_{polarizing} individually to each of electrode pairs. Alternatively, it's possible to only apply at least 4V_{polarizing} between the two electrodes 616 and 622 to polarize the regions of ferroelectric film in the central portion, and apply at least 4V_{polarizing} between the two electrodes 624 and 630 to polarize the regions of ferroelectric film in the peripheral portion. The latter is more convenient.

Both in embodiment 1 or embodiment 2, or in a case where the number of electrode pairs of a piezoelectric micro acoustic sensor based on ferroelectric materials is different from that of embodiment 1 and embodiment 2, when applying a voltage to a plurality of electrode pairs connected in series to polarize the ferroelectric film therebetween, it's preferable that each central electrode pair has a same area, and each peripheral electrode pair has a same area, so that every electrode pair has a same voltage which is not less than V_{polarizing}. Therefore, the regions of ferroelectric film sandwiched between each electrode pair are equally polarized.

Further, when a diaphragm vibrates as driven by acoustic waves, the stress within the film generally reaches its maximum value at the center, and an electrode pair disposed at the location of a ferroelectric film with a maximum stress value will have a maximum voltage induced thereon, so that central electrode pairs shall be placed near the center of the film as much as possible. In the case where the ferroelectric film of a sensor has a square shape, the stress within the film also reaches its maximum value near the middle of each of the four sides. Hence it's preferable to place peripheral electrode pairs at the middle of each side of the film, so as to further increase the voltage sensitivity of the piezoelectric ferroelectric micro acoustic sensor based on ferroelectric materials.

The number N of electrode pairs disposed in a same stress state portion is not limited to 2 or 4 as described in the embodiments. If it can be implemented under the current technical conditions, it's preferable to provide more electrode pairs (say, 8 central electrode pairs and 8 peripheral electrode pairs), and connect the electrode pairs with the same method described above. In this way, the voltage sensitivity of the piezoelectric micro acoustic sensor based on ferroelectric materials according to embodiments of the present invention will be further improved.

It is described above that no electrode pair extends from one stress state portion to the other, however, in practice, it's also acceptable if a electrode pair only extends across the border line (209) a little bit, since the voltage sensitivity will not deteriorate seriously.

By disposing a plurality of electrode pairs in a same stress state portion, and controlling the direction of polarization of the regions of ferroelectric film between the electrode pairs and connecting the plurality of electrode pairs in series, the voltage sensitivity of a piezoelectric micro acoustic sensor based on ferroelectric materials of the invention is improved significantly.

While the invention has been described above, it will be apparent to those skilled in the art that various modifications may be made without departing from the spirit and scope of the invention. All such modifications are intended to be included within the scope of the following claims.

What is claimed is:

1. A piezoelectric ferroelectric micro acoustic sensor based on ferroelectric materials, comprising:
a ferroelectric film; and
a plurality of electrode pairs, a lower electrode and an upper electrode in each pair being disposed on either side of the ferroelectric film to mutually face each other,
wherein more than one electrode pairs are provided within at least one of the central portion and the peripheral portion of the ferroelectric film,
a polarizing voltage V_{polarizing} is applied to each electrode pair so that the region of the ferroelectric film between said each electrode pair is polarized along its thickness direction,
within a same stress state portion of the ferroelectric film, the regions of the ferroelectric film between neighboring electrode pairs are polarized in opposite directions, so that opposite voltages are induced on neighboring electrode pairs disposed within a same stress state portion when the ferroelectric film vibrates,
in either stress state portion of the ferroelectric film, the electrode pairs are connected in series by electrically connecting every electrode pair with its neighboring pair, and between said two neighboring pairs ferroelectric film are polarized in opposite directions,
and the electrode pairs connected in series in both the stress state portions are connected in series again, two regions of ferroelectric film sandwiched between the electrode pair in the central portion and between the electrode pair in the peripheral portion that are electrically connected to each other, are polarized in the same direction, so that all the electrode pairs are connected in series, and the output voltage of all of the thus connected electrode pairs equals to the sum of voltages of each single electrode pair.

2. A piezoelectric micro acoustic sensor based on ferroelectric materials of claim 1, wherein,
each of said electrode pairs is disposed within either the central portion or peripheral portion of the ferroelectric film, without extending from one stress state portion to the other.

3. A piezoelectric micro acoustic sensor based on ferroelectric materials of claim 1, wherein,
said electrode pair extends from one stress state portion to the other, the area of the part of the electrode pair extending to the other stress state portion being much smaller than that in the original stress state portion.

4. A piezoelectric micro acoustic sensor based on ferroelectric materials of claim 1, wherein,
the electrode pairs within the central portion are disposed close to the center of the central portion, where the stress within the ferroelectric film reaches its maximum value.

5. A piezoelectric micro acoustic sensor based on ferroelectric materials of claim 1, further comprising:
a substrate;
a supporting layer which is rigidly bonded to the substrate, said lower electrodes, ferroelectric film and upper electrodes being stacked sequentially on the supporting layer;
an isolation layer, provided outside the substrate, the supporting layer, the lower electrodes, the ferroelectric film, and the upper electrodes; and
metal bonding layers, provided on top of the isolation layer,
wherein,
via holes are provided on the isolation layer, through which the metal bonding layers are electrically connected to said lower electrodes and upper electrodes respectively, and
an opening is provided on said substrate, so that the ferroelectric film may vibrate as driven by acoustic waves.

6. A piezoelectric micro acoustic sensor based on ferroelectric materials of claim 5, wherein,
said opening is round.

7. A piezoelectric micro acoustic sensor based on ferroelectric materials of claim 6, wherein,
central electrode pairs are disposed within a concentric circle of the opening having a radius of 0.7R, R being the radius of the round opening, and
peripheral electrode pairs are disposed outside said concentric circle.

8. A piezoelectric micro acoustic sensor based on ferroelectric materials of claim 5, wherein,
said opening is a square.

9. A Piezoelectric micro acoustic sensor based on ferroelectric materials of claim 8, wherein,
central electrode pairs are disposed within a square with side length of 0.7L, whose centroid coincides with that of the opening, L being the side length of the opening, and
peripheral electrode pairs are disposed outside said square with side length of 0.7L.

10. A piezoelectric micro acoustic sensor based on ferroelectric materials of claim 9, wherein,
said peripheral electrode pairs are disposed close to the middle of each of the four sides of the opening.

11. A piezoelectric micro acoustic sensor based on ferroelectric materials of claim 1, wherein,
N is the number of electrode pairs disposed within the central portion or within the peripheral portion, which are connected in series, N being an integer not smaller than 1, and
a voltage not smaller than NV_{polarizing} is applied to the two end electrodes of the N electrode pairs, so that the ferroelectric film between said each electrode pair is polarized along its thickness direction.

12. A piezoelectric micro acoustic sensor based on ferroelectric materials of claim 11, wherein,
said electrode pairs within the central portion have a same area, and
said electrode pairs within the peripheral portion have a same area.

13. A piezoelectric micro acoustic sensor based on ferroelectric materials of claim 1, wherein,
a polarizing voltage is applied individually to each electrode pair.

14. A piezoelectric micro acoustic sensor based on ferroelectric materials of claim 5, wherein,
said substrate is made of one of the following: silicon, GaAs, GaN, and InP.

15. A piezoelectric micro acoustic sensor based on ferroelectric materials of claim 1, wherein,
said ferroelectric film is made of one of the following: PZT, PT, and PVDF.

16. A piezoelectric micro acoustic sensor based on ferroelectric materials of claim 1, wherein,
all of said plurality of electrode pairs are disposed within the central portion.

17. A piezoelectric micro acoustic sensor based on ferroelectric materials of claim 1, wherein,
all of said plurality of electrode pairs are disposed within the peripheral portion.
